(19) United States
(12) Patent Application Publication
(10) Pub. No.: US 2008/0188062 A1
(43) Pub. Date: Aug. 7, 2008

(54) Method of forming microcrystalline silicon film

(76) Inventors: Chi-Lin Chen, Hsinchu City (TW); Chin-Jen Huang, Hsinchu City (TW)

Correspondence Address: Akin Gump LLP - Silicon Valley, 3000 El Camino Real, Two Palo Alto Square, Suite 400, Palo Alto, CA, 94306, US

(21) Appl. No.: 11/701,762

(22) Filed: Feb. 2, 2007

(51) Int. Cl. H01L 21/20

(52) U.S. Cl. 438/483; 438/478; 257/E21.09

(57) ABSTRACT

A method capable of making a semiconductor device in a plasma-assisted chemical vapor deposition (CVD) system including a chamber having a first electrode and a second electrode spaced apart from one another, the method comprising providing a substrate on the second electrode, the substrate including a surface being exposed to the first electrode, forming a semiconductor film on the surface of the substrate and applying a first bias to the second electrode during a nucleation stage of the semiconductor film till a predetermined thickness of the semiconductor film is reached, and applying a second bias to the second electrode after the predetermined thickness of the semiconductor film is reached.

### BACKGROUND OF THE INVENTION

The present invention relates generally to a method of semiconductor fabrication, and more particularly, to a method of forming a microcrystalline silicon (μc-Si) film or a μc-Si alloy film by a plasma-assisted chemical vapor deposition (“CVD”) process.

Microcrystalline silicon materials, such as microcrystalline silicon films, have many applications due to its material properties and characteristics. One of the applications includes the solar cell application. Many other applications, such as applications require semiconductor devices or circuits with superior electrical characteristics, also frequently rely on the use of microcrystalline silicon materials. Using the solar cell application as an example, the following illustrates one application of microcrystalline silicon materials

Solar energy is one of the most important energy sources that have become available in recent years. A great deal of attention has been paid to photovoltaic devices, i.e., solar cells, which are capable of converting solar radiation into electrical energy based on the photovoltaic effect. Solar cells, powered by the virtually limitless energy of the sun, need not be replenished with fossil fuels and therefore have been applied to satellites, space and mobile communications. Given the increasing demands for energy saving, effective utilization of resources and prevention of environmental pollution, a solar cell has become an attractive device for generating energy.

Solar cells may be fabricated on silicon (Si) wafers. However, the cost of electricity generated using wafer-type solar cells is relatively high as compared to electricity generated by the traditional methods, such as fossil-fuel-burning power plants. To make solar cells more economically viable, low-cost, thin-film growth techniques that deposit high-quality light-absorbing semiconductor materials have been developed. These thin-film approaches grow solar cells or solar cell modules on large-area substrates, which may achieve cost-effective fabrication and allow versatile modular designs. Fabrication of large-area solar cells typically uses amorphous semiconductor thin films, such as amorphous silicon films. Certain researches and studies have found that a stacked or tandem solar cell may have improved energy conversion efficiency. Furthermore, researches and studies have also found that microcrystalline silicon (μc-Si) films or nanocrystalline silicon films may enhance the conductivity of a solar cell and absorb different wavelengths of light across the sunlight spectrum, which may further improve the energy conversion efficiency. The μc-Si films may be one of the desirable materials for fabricating next-generation solar cells. However, depending on the processing techniques, fabricating solar cells based on the μc-Si films may have certain issues, such as issues relating to thin film quality, interface property, thin film deposition rate and/or large-area thin film uniformity.

### BRIEF SUMMARY OF THE INVENTION

Examples of the present invention may provide a method capable of making a semiconductor device in a plasma-assisted chemical vapor deposition (CVD) system including a chamber having a first electrode and a second electrode spaced apart from one another, the method comprising providing a substrate on the second electrode, the substrate including a surface being exposed to the first electrode, forming a semiconductor film on the surface of the substrate and applying a first bias to the second electrode during a nucleation stage of the semiconductor film till a predetermined thickness of the semiconductor film is reached, and applying a second bias to the second electrode after the predetermined thickness of the semiconductor film is reached.

Some examples of the present invention may also provide a method capable of making a semiconductor device in a plasma-assisted chemical vapor deposition (CVD) system including a chamber having a first electrode and a second electrode spaced apart from one another, the method comprising providing a substrate on the second electrode, the substrate including a surface being exposed to the first electrode, forming a semiconductor film on the surface of the substrate, applying a negative bias to the second electrode for generating nucleation sites on the surface of the substrate during the formation of the semiconductor film for a predetermined time, and applying a positive bias to the second electrode for reducing defect density on the surface of the substrate after the predetermined time.

Examples of the present invention may further provide a method capable of making a semiconductor film in a plasma-assisted chemical vapor deposition (CVD) system including a chamber having a first electrode and a second electrode spaced apart from one another, the method comprising providing a substrate on the second electrode, the substrate including a surface being exposed to the first electrode, forming a first semiconductor film over the surface, applying a first bias to the second electrode during the formation of the first semiconductor film, forming a second semiconductor film over the first semiconductor film, and applying a second bias to the second electrode during the formation of the second semiconductor film.

Additional features and advantages of the present invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1 is a schematic diagram of a system capable of forming a microcrystalline silicon (μc-Si) film consistent with an example of the present invention;

FIG. 2 is a schematic diagram illustrating a method of forming a μc-Si film consistent with an example of the present invention;

FIGS. 3A to 3D are exemplary plots illustrating an output voltage of the second power supply illustrated in FIG. 1;

FIGS. 4A and 4B are examples of transmission electron microscope (TEM) photos showing experimental results of a method consistent with an example of the present invention;

FIG. 4C is a plot from a Raman spectrum analysis of the material illustrated in FIGS. 4A and 4B; and

FIG. 5 is a flow diagram illustrating a method of forming semiconductor layers of a solar cell consistent with an example of the present invention.

### DETAILED DESCRIPTION OF THE INVENTION

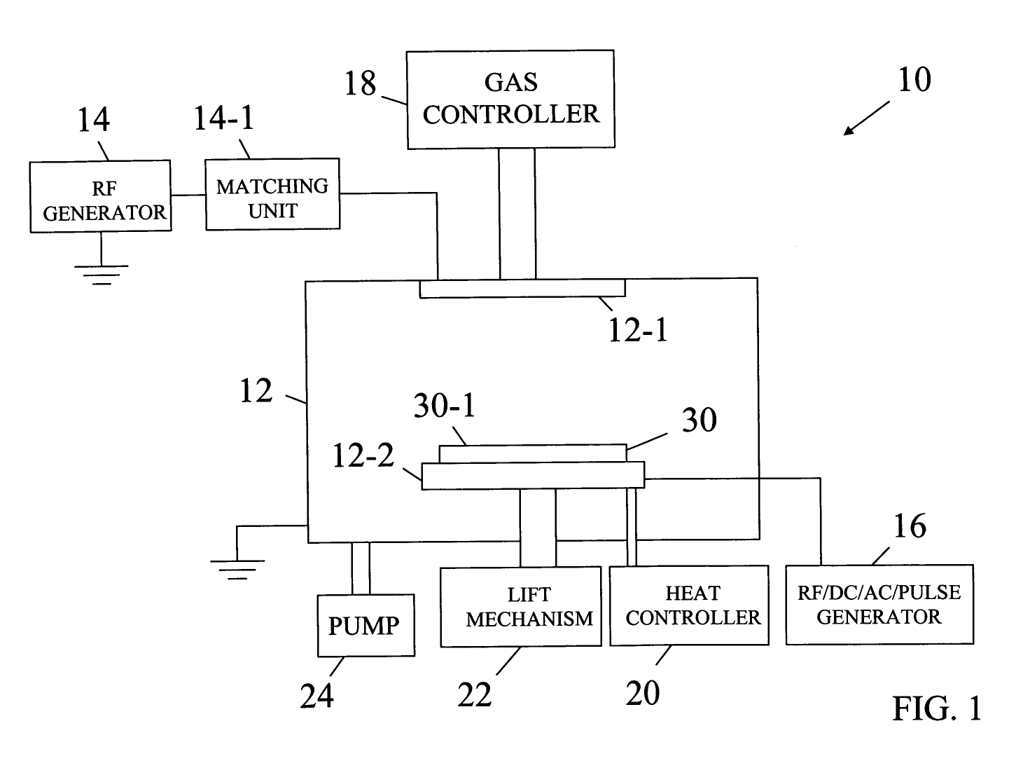

FIG. 1 is a schematic diagram of a system 10 capable of forming a microcrystalline silicon (μc-Si) film consistent with an example of the present invention. The μc-Si film or nanocrystalline silicon film may refer to a polycrystalline silicon film having a grain size ranging from approximately 10 to 100 nanometer (nm). However, the range may be different in particular applications. The system 10 in other examples may also be capable of forming microcrystalline silicon carbide (μc-SiC), microcrystalline silicon germanium (μc-SiGe), amorphous silicon and amorphous silicon germanium (a-SiGe). Referring to FIG. 1, the system 10 may include a chamber 12, a first power generator 14 and a second power generator 16. As an example, the system 10, except the second power generator 16, may include a model AKT-1600 plasma-enhanced chemical vapor deposition (PECVD) system manufactured by Applied Komatsu Technology, a high density plasma CVD (HDPCVD) system manufactured by Applied Materials, Inc., an inductively coupled plasma CVD (ICP-CVD) system, a capacitively coupled plasma (CCP) CVD, an electron cyclotron resonance CVD (ECRCVD), a microwave plasma CVD (MWCVD) and a remote plasma source system. The present invention, however, is not limited to the above-mentioned systems and may be used with other commercially available deposition systems.

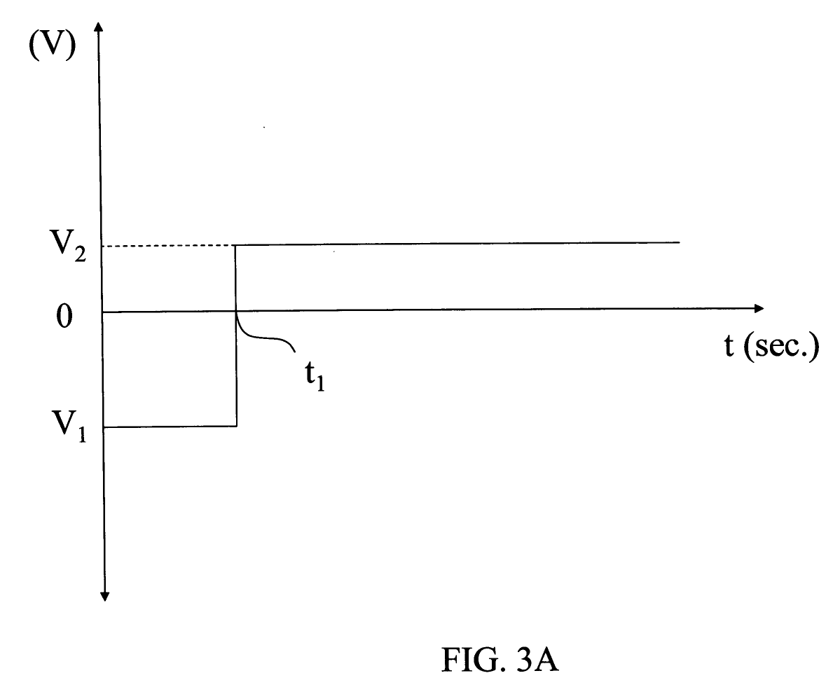

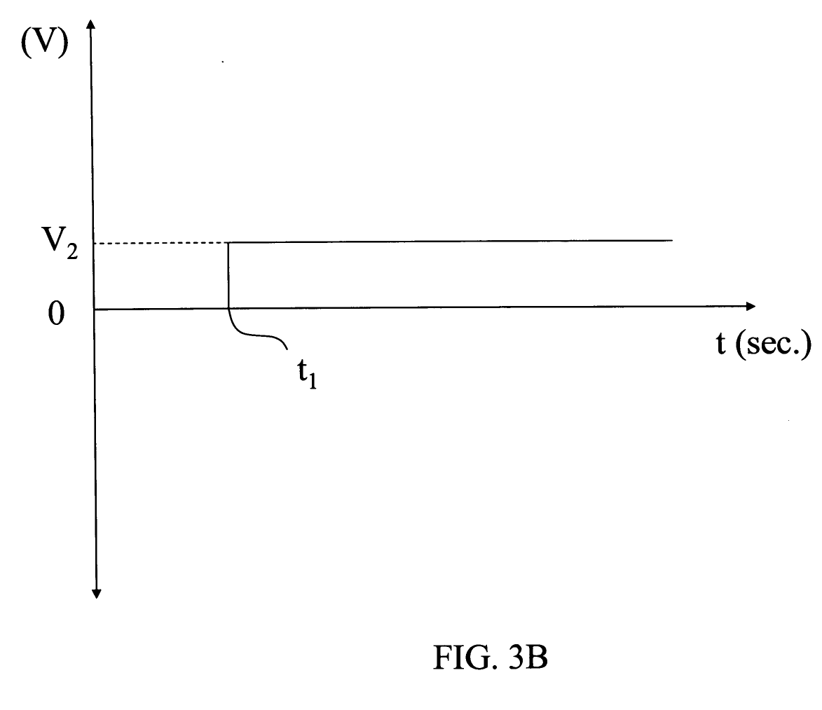

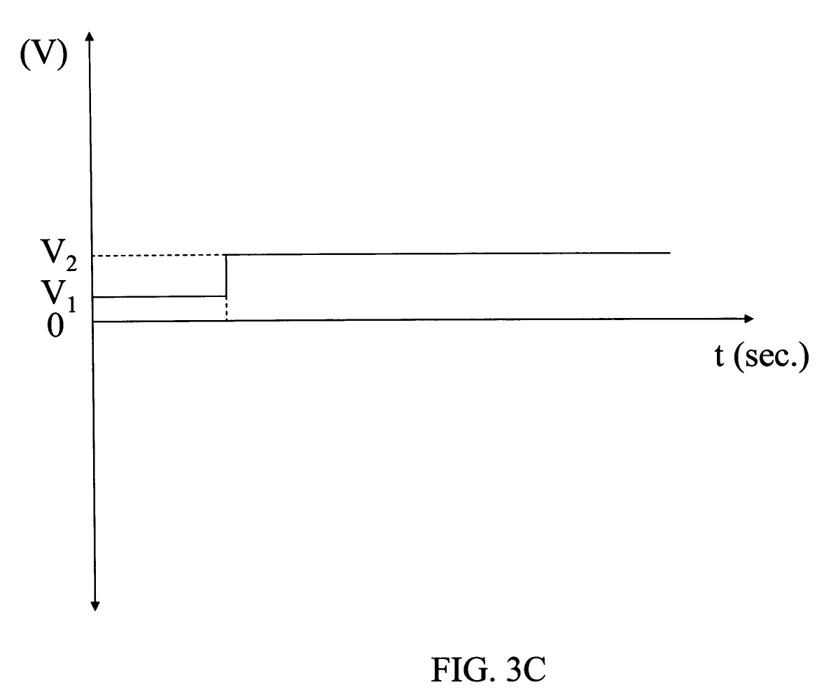

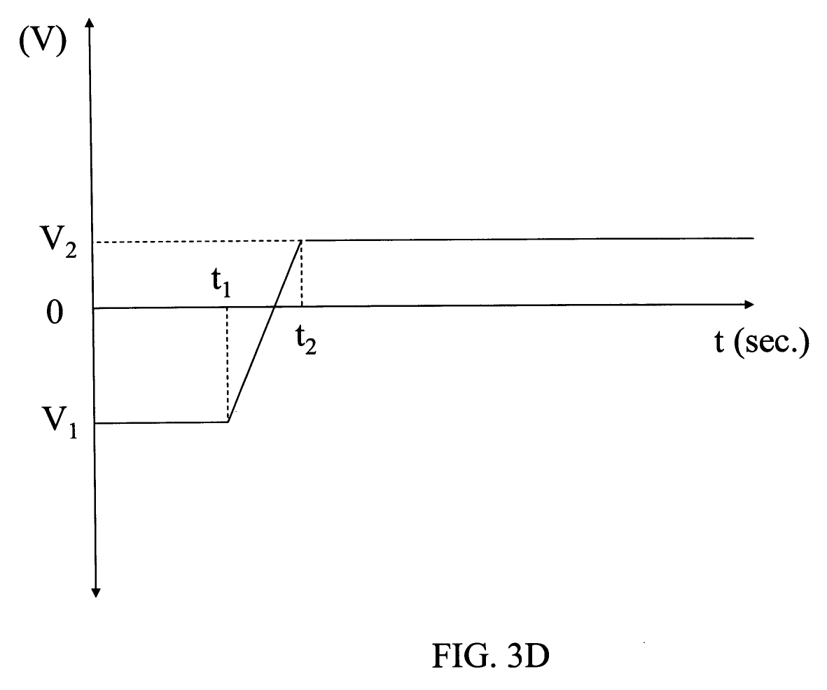

A substrate 30, which may include one of a glass, polymer and metal foil substrate, is placed in the chamber 12. The chamber 12 may be equipped with a pair of parallel plate electrodes including a first electrode 12-1 and a second electrode 12-2. The first electrode 12-1 may serve as a gas inlet manifold or shower head through which a reactant gas provided by a gas controller 18 flows into the chamber 12. The second electrode 12-2, spaced apart from the first electrode 12-1 by, for example, several inches, may function to support or hold the substrate 30. During deposition, a radio frequency (RF), very high frequency (VHF) or microwave provided by the first power generator 14 through a matching network 14-1 is applied to the first electrode 12-1 to produce plasma within the reactant gas in the chamber 12. The plasma causes the reactant gas to decompose and deposit a layer of material onto an exposed surface 30-1 of the substrate 30. The second power supply 16 may provide an RF voltage, a direct current (DC) voltage, an alternating current (AC) voltage or at least one pulse voltage to the second electrode 12-2 to create an electrical field between the first electrode 12-1 and the second electrode 12-2. The deposition process and operation of the second power supply 16 will be later discussed in detail by reference to FIGS. 3A to 3C.

The system 10 may further include a heat controller 20, a lift mechanism 22 and a pump 24. The heat controller 20 may power a heater (not shown) for heating the substrate 30 during deposition in order to achieve or maintain the second electrode 12-2 at an appropriate temperature level. The lift mechanism 22 is provided to support the second electrode 12-2 at an appropriate elevation level. The pump 24 may be used to evacuate the chamber 12 to a state of vacuum.

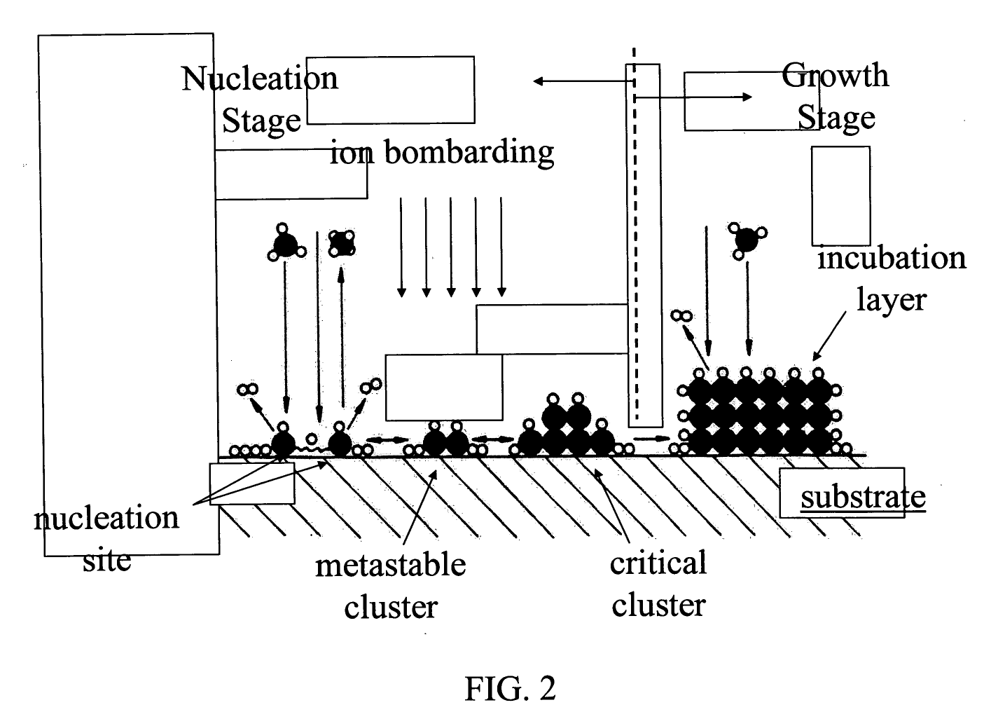

FIG. 2 is a schematic diagram illustrating a method of forming a μc-Si film consistent with an example of the present invention. The deposition process is a result of chemical reactions between reactive molecular precursors and the substrate 30. Initial atoms and molecules that will constitute the film are delivered as precursors, which are fed from the gas controller 18 illustrated in FIG. 1. The desired reactions are to deposit a film on the surface 30-1 of the substrate 30 and eliminate extra atoms or molecules that comprise the precursors. In one example, the surface 30-1 of the substrate 30 may include a layer of doped tin oxide such as ZnO:Al or doped zinc oxide such as SnO₂:F, which may be formed over the substrate 30 by a conventional physical vapor deposition (PVD) process or another suitable process. The ZnO:Al or SnO₂:F layer may function to serve as a first electrode for a solar cell.

Referring to FIG. 2, the deposition process may include a nucleation stage and a growth stage. The nucleation stage is assumed when a film of stable material is deposited on nucleation sites on the surface 30-1 of the substrate 30. The substrate 30 has many bonding locations on the surface 30-1, where chemical binding occurs during deposition, causing gaseous atoms and molecules to chemically attach to the surface 30-1. However, the reaction does not occur at all of the potential bonding locations. Generally, nucleation sites, which have irregular topology or impurities, are likely to trap the molecular precursors. To provide more of such nucleation sites, also referring to FIG. 1, the second power supply 16 in one example may provide a negative bias to the second electrode 12-2 during the nucleation stage to generate an electrical field between the first electrode 12-1 and the second electrode 12-2, resulting in an ion bombarding effect on the surface 30-1. The ion bombarding may facilitate formation of nucleation sites for initial reaction products, that is, nucleation seeds. The nucleation seeds are immobile and diffusing molecular precursors have a high probability to collide with them and react, resulting in the growing of metastable clusters. As the metastable clusters grow larger, most of the collisions occur at the boundaries of the metastable clusters, which may result in a seed layer. As the metastable clusters further grow three-dimensionally, most of the binding and reaction processes occur on the upper surfaces of the metastable clusters, resulting in the formation of critical clusters. During the growth stage, eventually, the vertical growth of the critical clusters results in the formation of grains, which finally coalesce into a continuous film.

On the other hand, however, large-sized or heavy ions in the molecular precursors may damage the surface 30-1 of the substrate 30 when accelerated toward the surface by the electrical field during the nucleation stage. In the example that a ZnO:Al or SnO₂:F layer has formed on the substrate 30, since the material ZnO:Al or SnO₂:F exhibit crystalline characteristics and relatively high conductivity of more than, for example, 10²⁰/cm³ free electrons, such damage on the surface 30-1 may not adversely affect the conductivity or cause any significant increase in defect density. Furthermore, the crystalline characteristics may facilitate the nucleation. To alleviate the potential damage, the second power supply 16 in another example may provide a positive or reference bias to the second electrode 12-2 during the nucleation stage.

In one example consistent with the present invention, the RF power provided by the first power supply 14 is approximately 600 watts at a frequency of approximately 13.56 MHz. The density of plasma generated is approximately 10¹¹ to 10¹³ cm⁻³, which may facilitate the nucleation with a shorter incubation time and thinner incubation layer as compared to a lower density of one or two orders less. The chamber 12 may be evacuated to a pressure of approximately 10⁻³ Torr. The reactant gases may include silane (SiH₄), hydrogen (H₂) and Argon (Ar). In one example, Ar is approximately 0 to 50 sccm, SiH₄ is approximately 50 sccm, and the ratio of SiH₄ to H₂ is approximately 1:10 to 1:100. The substrate 30 is maintained at a temperature of approximately 25° C. to 500° C. The incubation layer may range approximately from 30 to 50 nanometer (nm), under which the thickness an amorphous silicon may be crystallized into a polycrystalline silicon.

During the growth stage, a chemical erosion process may be conducted to remove weakly bonded amorphous or silicon molecules on the upper surface of the incubation layer. In another example, however, the chemical erosion process may be conducted during the nucleation stage. Since separated nucleation sites can result in the formation of grain boundaries and voids on the surface 30-1 of the substrate 30, where potential bonding sites failed to bond with the molecular precursors, the removal of the weakly bonded materials may help reduce the incubation time and the incubation layer thickness. An erosive gas including SiF₄ and H₂ or SiCl₄ and H₂ is used in the chemical erosion process. In one example consistent with the present invention, the ratio of SiF₄ to H₂ ranges from approximately 1:10 to 1:100. In another example, SiF₄ is 1 sccm and H₂ is 10 sccm.

When the film grows to a predetermined thickness during the nucleation stage, the second power supply 16 may provide a positive bias to the second electrode 12-2 in order to achieve a condensed silicon film. The positive bias may restrain ion bombarding and reduce defect density on the surface 30-1. During the growth stage, the reactant gas Ar is cut off, SiH₄ is maintained at approximately 50 sccm, and the ratio of SiH₄ to H₂ is approximately 1:10 to 1:100.

FIGS. 3A to 3D are exemplary plots illustrating an output voltage of the second power supply illustrated in FIG. 1. Referring to FIG. 3A, the second power supply 16 in one example may provide a DC bias ranging from approximately −5 to −150 volts to the second electrode 12-2 during the nucleation stage. As has been previously discussed, the negative bias may help increase nucleation sites on the surface 30-1 and therefore facilitate the nucleation. In another example, the second power supply 16 may provide an AC bias ranging from approximately −150 to 50 volts at a frequency of approximately 0 to 400 Hz. In still another example, the second power supply 16 may provide at least one pulse voltage, for example, in the form of a square wave. The pulse voltage may range from approximately −150 to 50 volts at a frequency of approximately 0 to 400 Hz with a pulse width of approximately 1 to 10 μm/sec.

Furthermore, the second voltage supply 16 may provide a DC bias ranging from approximately 5 to 150 volts to the second electrode 12-2 when the film grows to a predetermined thickness that enables the film to serve as a seed layer. As an example, the predetermined thickness may be a quarter (¼) or one third (⅓) of the full thickness of the film eventually made. Referring to FIG. 3A, the predetermined may occur at a time t₁, which may be ¼ or ⅓ of the entire process time. As has been previously discussed, since a seed layer has been generated during the nucleation stage, the positive bias may help restrain ion bombarding and therefore reduce defect density on the seed layer. In another example, the second power supply 16 may provide an AC bias ranging from approximately −50 to 150 volts at a frequency of approximately 0 to 400 Hz. In still another example, the second power supply 16 may provide at least one pulse voltage, for example, in the form of a square wave. The pulse voltage may range from approximately −50 to 150 volts at a frequency of approximately 0 to 400 Hz with a pulse width of approximately 1 to 10 μm/sec.

Skilled persons in the art will understand that the polarity of the voltage provided by the second power supply 16 may be smoothly changed from negative to positive, as illustrated in FIG. 3D. Referring to FIG. 3D, the second power supply 16 may provide a negative bias till the time point t₁ during the nucleation stage, and provide a positive bias at a time point t₂ during the rest of the nucleation stage or during the growth stage.

Referring to FIG. 3B, the second power supply may be turned off or provide a reference voltage of 0 volt to the second electrode 12-2 during the nucleation stage. After the predetermined thickness is reached, the second power supply 16 may provide a DC bias ranging from approximately 5 to 150 volts to the second electrode 12-2, an AC bias ranging from approximately −0 to 150 volts at a frequency of approximately 0 to 400 Hz, or at least one pulse voltage ranging from approximately 0 to 150 volts at a frequency of approximately 0 to 400 Hz with a pulse width of approximately 1 to 10 μm/sec.

Referring to FIG. 3C, the second voltage supply 16 may provide a DC bias ranging from approximately 0 to 20 volts to the second electrode 12-2 during the nucleation stage. After a seed layer is formed, the second power supply 16 may provide a DC bias ranging from approximately 20 to 150 volts to the second electrode 12-2, an AC bias ranging from approximately 0 to 150 volts at a frequency of approximately 0 to 400 Hz, or at least one pulse voltage ranging from approximately 0 to 150 volts at a frequency of approximately 0 to 400 Hz with a pulse width of approximately 1 to 10 μm/sec.

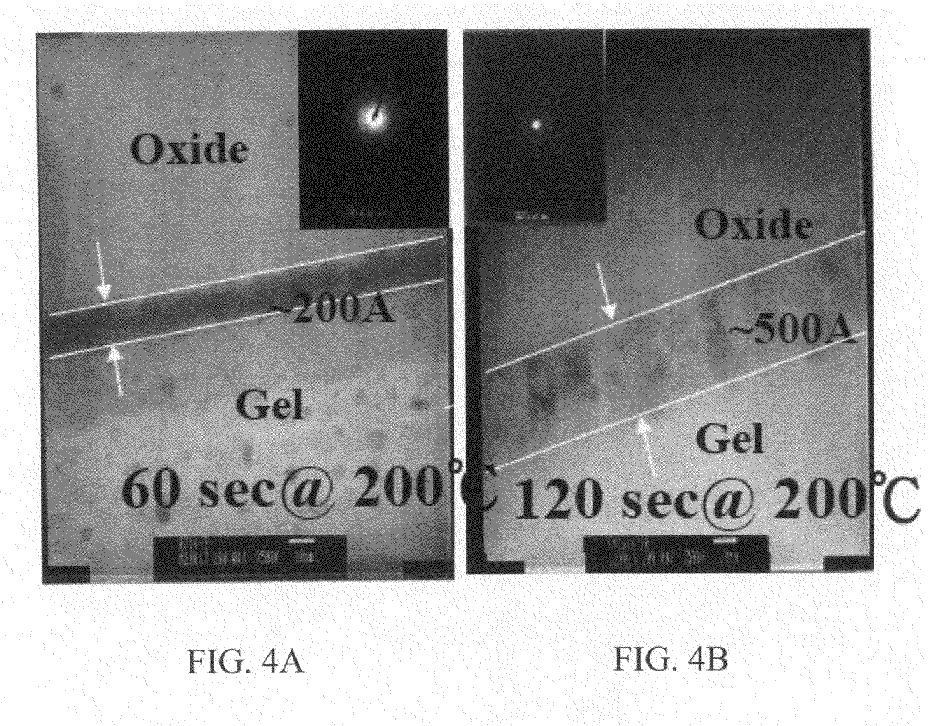

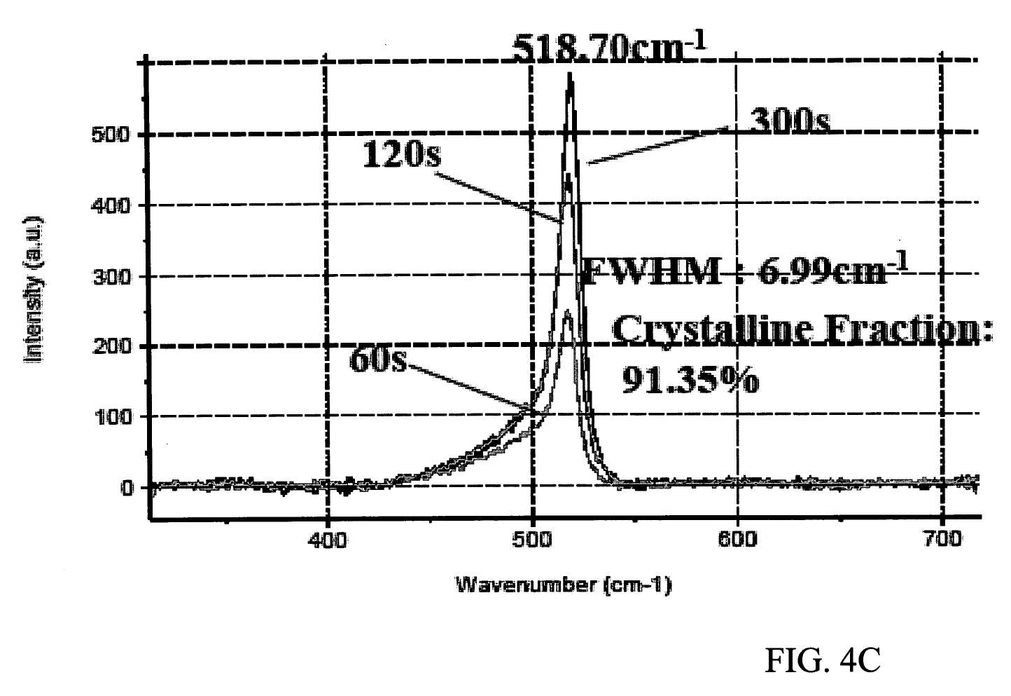

FIGS. 4A and 4B are examples of transmission electron microscope (TEM) photos showing experimental results of a method consistent with an example of the present invention. In conducting the experiments, the substrate 30 is maintained at a temperature of approximately 200° C. and the substrate surface 30-1 includes an oxide layer. Referring to FIG. 4A, after 60 seconds, a μc-Si film of approximately 20 nm is formed over the oxide layer. Referring to FIG. 4B, as the deposition process proceeds, the μc-Si film may grow to a thickness of approximately 50 nm.

FIG. 4C is a plot from a Raman spectrum analysis of the material illustrated in FIGS. 4A and 4B. Referring to FIG. 4C, the full width at half maximum (FWHM) value is approximately 6.99 cm⁻¹ and the crystalline fraction is approximately 91.35%. Furthermore, the signal occurring at the wave number of approximately 518.70 cm⁻¹ may indicate that a μc-Si state has reached. Skilled persons in the art will understand that if the surface 30-1 includes a ZnO:Al or SnO₂:F layer (which exhibits crystalline characteristics), a μc-Si film may grow faster or thicker than that on a surface including an oxide layer.

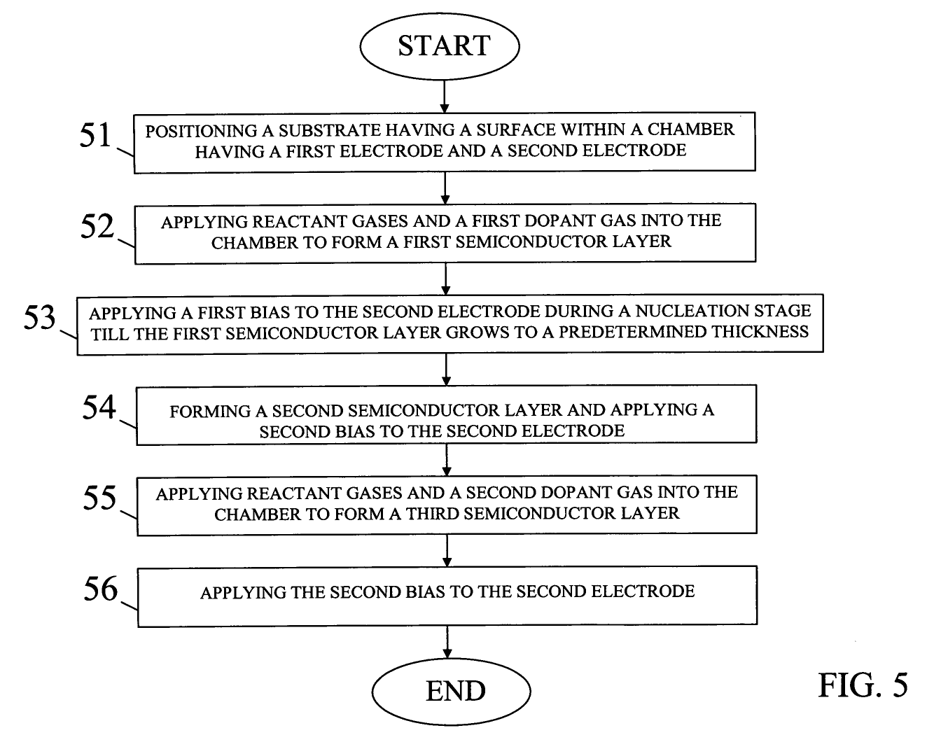

FIG. 5 is a flow diagram illustrating a method of forming semiconductor layers of a solar cell consistent with an example of the present invention. The semiconductor layers of a solar cell may generally include a p-i-n structure that comprises a p-type layer, an n-type layer and an intrinsic layer between the p-type and n-type layers. Furthermore, a stack-type or tandem solar cell may generally include a top cell having a first p-i-n structure and a bottom cell having a second p-i-n structure. For the purpose of simplicity, a method according to the present invention for forming the single p-i-n structure is discussed. Skilled persons in the art will understand that the method may be applicable to other structures such as the stack-type structure.

Referring to FIG. 5, at step 51, a substrate is positioned within a chamber of a plasma assisted CVD system. The substrate may be made of, for example, glass, polymer or metal foil. The plasma assisted CVD system may include one of an ICP CVD, CCP CVD, ECRCVD, MWCVD and remote plasma source CVD system. The chamber may be equipped with a first electrode and a second electrode. The substrate is supported over the second electrode with a surface of the substrate exposed to the first electrode. The surface of the substrate may be formed with a ZnO:Al or SnO₂:F layer or other suitable layer that may serve as an electrode terminal of the solar cell being fabricated.

At step 52, the reactant gases such as silane (SiH₄), hydrogen (H₂) and Argon (Ar) and a first dopant gas are applied into the chamber. The first dopant gas may include a dopant hydride such as B₂H₆ or a dopant fluoride such as BF₃, which is used to form a p-type layer on the surface of the substrate. At step 53, during a nucleation stage, a first bias is applied to the second electrode. The first bias may include one of a negative bias, a reference level and a positive bias. In one example, a DC bias ranging from approximately −5 to −150 volts is applied to the second electrode. In another example, a DC bias ranging from approximately 0 to 20 volts is applied to the second electrode. Given a desired film thickness of 20 to 40 nm, when the p-type layer grows to a predetermined thickness of approximately 10 to 15 nm at a deposition rate of approximately 0.1 to 1 nm/sec, the first bias is turned off, and the second bias may be turned on immediately or at a later time. When the p-type layer grows to the desired thickness for a process time of approximately 40 to 4000 seconds, the reactant and dopant gases are cut off. The residual gases and materials in the chamber are exhausted. The p-type layer may include at least one of μc-Si, μc-SiC or μc-SiGe.

Next, at step 54, reactant gases similar to those used to form the p-type layer are applied to the chamber in order to form an intrinsic layer. The second bias is applied to the second electrode to reduce defect density. In one example, a DC bias ranging from approximately 20 to 50 volts is applied to the second electrode. When the intrinsic layer grows to a thickness of approximately 3 um, the reactant gases are cut off and residual gases and materials within the chamber are exhausted. The second bias is turned off. The intrinsic layer may include at least one of amorphous silicon, ac-SiGe, μc-Si, μc-SiC or μc-SiGe.

Next, at step 55, the reactant gases similar to those used to form the p-type layer and a second dopant gas are applied into the chamber. The second dopant gas may include a dopant hydride such as PH₃, which is used to form an n-type layer over the surface of the substrate. At step 56, the second bias is applied to the second electrode. When the n-type layer grows to a thickness of approximately 20 to 40 nm, the reactant and dopant gases are cut off and the second bias is turned off. The residual gases and materials in the chamber may be exhausted. The n-type layer may include at least one of μc-Si, μc-SiC or μc-SiGe.

It will be appreciated by those skilled in the art that changes could be made to the examples described above without departing from the broad inventive concept thereof. It is understood, therefore, that this invention is not limited to the particular examples disclosed, but it is intended to cover modifications within the spirit and scope of the present invention as defined by the appended claims.

Further, in describing representative examples of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of the steps in the order written, and one skilled in the art can readily appreciate that the sequences may be varied and still remain within the spirit and scope of the present invention.

I/we claim:

1. A method capable of making a semiconductor device in a plasma-assisted chemical vapor deposition (CVD) system including a chamber having a first electrode and a second electrode spaced apart from one another, the method comprising:
providing a substrate on the second electrode, the substrate including a surface being exposed to the first electrode;
forming a semiconductor film on the surface of the substrate and applying a first bias to the second electrode during a nucleation stage of the semiconductor film till a predetermined thickness of the semiconductor film is reached; and
applying a second bias to the second electrode after the predetermined thickness of the semiconductor film is reached.

2. The method of claim 1 further comprising applying a negative bias to the second electrode during the nucleation stage for ion bombarding the surface of the substrate.

3. The method of claim 1 further comprising applying a positive bias to the second electrode during the nucleation stage for restraining ion bombarding on the surface of the substrate.

4. The method of claim 1 further comprising applying a positive bias to the second electrode after the predetermined thickness of the semiconductor film is reached.

5. The method of claim 1 further comprising applying one of a direct current (DC) voltage, an alternating current (AC) voltage and at least one voltage pulse to the second electrode during the nucleation stage.

6. The method of claim 1 further comprising applying one of a DC voltage, an AC voltage and at least one voltage pulse to the second electrode after the predetermined thickness of the semiconductor film is reached.

7. The method of claim 1, wherein the surface includes at least one of a doped tin oxide film and a doped zinc oxide film.

8. The method of claim 1, wherein the semiconductor film includes at least one of a microcrystalline silicon (μc-Si), a microcrystalline silicon carbide (μc-SiC) film, a microcrystalline silicon germanium (μc-SiGe) film, an amorphous silicon film or an amorphous silicon germanium (ac-Si) film.

9. A method capable of making a semiconductor device in a plasma-assisted chemical vapor deposition (CVD) system including a chamber having a first electrode and a second electrode spaced apart from one another, the method comprising:
providing a substrate on the second electrode, the substrate including a surface being exposed to the first electrode;
forming a semiconductor film on the surface of the substrate;
applying a negative bias to the second electrode for generating nucleation sites on the surface of the substrate during the formation of the semiconductor film for a predetermined time; and
applying a positive bias to the second electrode for reducing defect density on the surface of the substrate after the predetermined time.

10. The method of claim 9 further comprising applying one of a direct current (DC) voltage, an alternating current (AC) voltage and at least one voltage pulse to the second electrode.

11. The method of claim 9 further comprising applying one of a DC voltage, an AC voltage and at least one voltage pulse to the second electrode after the predetermined time.

12. The method of claim 9, wherein the negative bias ranges form approximately −5 to −150 volts.

13. The method of claim 9, wherein the positive bias ranges from approximately 5 to 150 volts.

14. The method of claim 9, wherein the semiconductor film includes at least one of a microcrystalline silicon (μc-Si), a microcrystalline silicon carbide (μc-SiC) film, a microcrystalline silicon germanium (μc-SiGe) film, an amorphous silicon film or an amorphous silicon germanium (ac-Si) film.

15. A method capable of making a semiconductor film in a plasma-assisted chemical vapor deposition (CVD) system including a chamber having a first electrode and a second electrode spaced apart from one another, the method comprising:
providing a substrate on the second electrode, the substrate including a surface being exposed to the first electrode;
forming a first semiconductor film over the surface;
applying a first bias to the second electrode during the formation of the first semiconductor film;
forming a second semiconductor film over the first semiconductor film; and
applying a second bias to the second electrode during the formation of the second semiconductor film.

16. The method of claim 15 further comprising:
forming a third semiconductor film over the second semiconductor film; and
applying the second bias to the second electrode during the formation of the third semiconductor film.

17. The method of claim 15 further comprising:
applying the first bias to the second electrode during the formation of the first semiconductor film till a predetermined thickness of the first semiconductor film is reached; and
applying the second bias to the second electrode during the formation of the first semiconductor film after the predetermined thickness of the first semiconductor film is reached.

18. The method of claim 15, wherein the first semiconductor film includes at least one of a microcrystalline silicon (μc-Si), a microcrystalline silicon carbide (μc-SiC) film or a microcrystalline silicon germanium (μc-SiGe) film.

19. The method of claim 15, wherein the second semiconductor film includes at least one of a μc-Si film, a μc-SiC film, a μc-SiGe film, an amorphous silicon film or an amorphous silicon germanium (ac-Si) film.

20. The method of claim 16, wherein the third semiconductor film includes at least one of a μc-Si film, a μc-SiC film or a μc-SiGe film.

21. The method of claim 15 further comprising:
applying a negative bias to the second electrode during the formation of the first semiconductor film; and
applying a positive bias to the second electrode during the formation of the second semiconductor film.

22. The method of claim 15 further comprising:
applying a first positive bias to the second electrode during the formation of the first semiconductor film; and
applying a second positive bias to the second electrode during the formation of the second semiconductor film.

23. The method of claim 16, further comprising:
applying a negative bias to the second electrode during the formation of the first semiconductor film; and
applying a positive bias to the second electrode during the formation of the third semiconductor film.
